(19) United States
(12) Patent Application Publication
(10) Pub. No.: US 2013/0146912 A1
(43) Pub. Date: Jun. 13, 2013

(54) ELECTRONIC DEVICE

(71) Applicants: Po-Jen Su, Tainan City (TW); Yun-Li Li, Tainan City (TW); Cheng-Yen Chen, Tainan City (TW); Gwo-Jiun Sheu, Tainan City (TW)

(72) Inventors: Po-Jen Su, Tainan City (TW); Yun-Li Li, Tainan City (TW); Cheng-Yen Chen, Tainan City (TW); Gwo-Jiun Sheu, Tainan City (TW)

(21) Appl. No.: 13/670,412

(22) Filed: Nov. 6, 2012

(30) Foreign Application Priority Data
Dec. 8, 2011 (TW) 100145326

(51) Int. Cl. H01L 33/60

(52) U.S. Cl. 257/98; 257/E33.072

(57) ABSTRACT

An electronic device including an insulating substrate, a plurality of conductive vias and a chip is provided. The insulating substrate has an upper surface and a lower surface opposite to each other. The conductive vias pass through the insulating substrate. The chip is disposed on the upper surface of the insulating substrate and includes a chip substrate, a semiconductor layer and a plurality of contacts. The semiconductor layer is located between the chip substrate and the contacts. The contacts are electrically connected to the conductive vias. The material of the insulating substrate and the material of the chip substrate are the same.

### CROSS-REFERENCE TO RELATED APPLICATION

This application claims the priority benefit of Taiwan application serial no. 100145326, filed on Dec. 8, 2011. The entirety of the above-mentioned patent application is hereby incorporated by reference herein and made a part of this specification.

### BACKGROUND OF THE INVENTION

1. Field of the Invention

The present invention relates to an electronic device, and more particularly to an electronic device having better heat dissipation efficiency.

2. Description of Related Art

Along with the development of the fabricating techniques, light emitting efficiency and luminance of the light emitting diodes (LEDs) are gradually improved, thereby complying with requirements for all kinds of products and expanding applications of the LED. In other words, in order to increase the brightness of the LEDs, besides solving the external package problems of the LED, a design of the LEDs with high power and high working current is required as well, so as to manufacture the LEDs featuring satisfactory luminance. However, under the circumstance of increasing the power and the working current of the LEDs, the LEDs may generate more heat, so the performance thereof is apt to be compromised by overheat, and overheat even may cause damage to the LEDs. Thus, how to have both satisfactory luminance and good heat dissipation effect is a great issue faced in development of the LEDs industry.

### SUMMARY OF THE INVENTION

The present invention provides an electronic device which has better heat dissipating efficiency.

The present invention provides an electronic device including an insulating substrate, a plurality of conductive vias and a chip. The insulating substrate has an upper surface and a lower surface opposite to the upper surface. The conductive vias pass through the insulating substrate. The chip is disposed on the upper surface of the insulating substrate. The chip includes a chip substrate, a semiconductor layer and a plurality of contacts. The semiconductor layer is located between the chip substrate and the contacts. The contacts are electrically connected to the conductive vias, and a material of the insulating substrate and a material of the chip substrate are the same.

According to one embodiment of the present invention, a specific heat of the insulating substrate and a specific heat of the chip substrate are higher than 650 J/Kg-K.

According to one embodiment of the present invention, a coefficient of thermal conductivity of the insulating substrate and a coefficient of thermal conductivity of the chip substrate are greater than 10 W/m-K.

According to one embodiment of the present invention, the insulating substrate and the chip substrate are transparent insulating substrates.

According to one embodiment of the present invention, the chip further includes a reflective layer disposed between the semiconductor layer and the contacts.

According to one embodiment of the present invention, the electronic device further includes an external circuit, and the chip is electrically connected to the external circuit through the conductive vias.

According to one embodiment of the present invention, the external circuit includes a lead frame, a circuit substrate or a printed circuit board.

According to one embodiment of the present invention, the electronic device further includes at least one heat dissipating element embedded in the lower surface of the insulating substrate.

According to one embodiment of the present invention, the insulating substrate further has at least one blind via disposed on the lower surface of the insulating substrate.

According to one embodiment of the present invention, the electronic device further includes a plurality of heat dissipating channels passing through the insulating substrate, wherein a top surface of each of the heat dissipating channels and the upper surface of the insulating substrate are coplanar, and a bottom surface of each of the heat dissipating channels and the lower surface of the insulating substrate are coplanar.

According to one embodiment of the present invention, a thickness of the insulating substrate is smaller than or equal to a thickness of the chip substrate.

According to one embodiment of the present invention, the thickness of the insulating substrate is 0.6 to one times the thickness of the chip substrate.

According to one embodiment of the present invention, a specific surface area of the insulating substrate is greater than a specific surface area of the chip substrate.

According to one embodiment of the present invention, the specific surface area of the insulating substrate is greater than 1.1 times the specific surface area of the chip substrate.

In light of the above, since the materials of the insulating substrate and the chip substrate are the same in the present invention, when the heat generated by the chip is transferred to the insulating substrate, the insulating substrate and the chip substrate having the same heat dissipating capacity, i.e., their coefficient of thermal conductivity being the same, the heat generated by the chip can be more effectively transferred to the external environment. Thus, the electronic device of the present invention has better heat dissipating efficiency.

In order to make the aforementioned and other features and advantages of the invention more comprehensible, embodiments accompanying figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is a schematic cross-sectional view of an electronic device according to an embodiment of the present invention.

FIG. 2 is a schematic cross-sectional view of an electronic device according to another embodiment of the present invention.

FIG. 3 is a schematic cross-sectional view of an electronic device according to another embodiment of the present invention.

FIG. 4 is a schematic cross-sectional view of an electronic device according to another embodiment of the present invention.

FIG. 5 is a schematic cross-sectional view of an electronic device according to another embodiment of the present invention.

FIG. 6 is a schematic cross-sectional view of an electronic device according to another embodiment of the present invention.

FIG. 7 is a schematic cross-sectional view of an electronic device according to another embodiment of the present invention.

### DESCRIPTION OF EMBODIMENTS

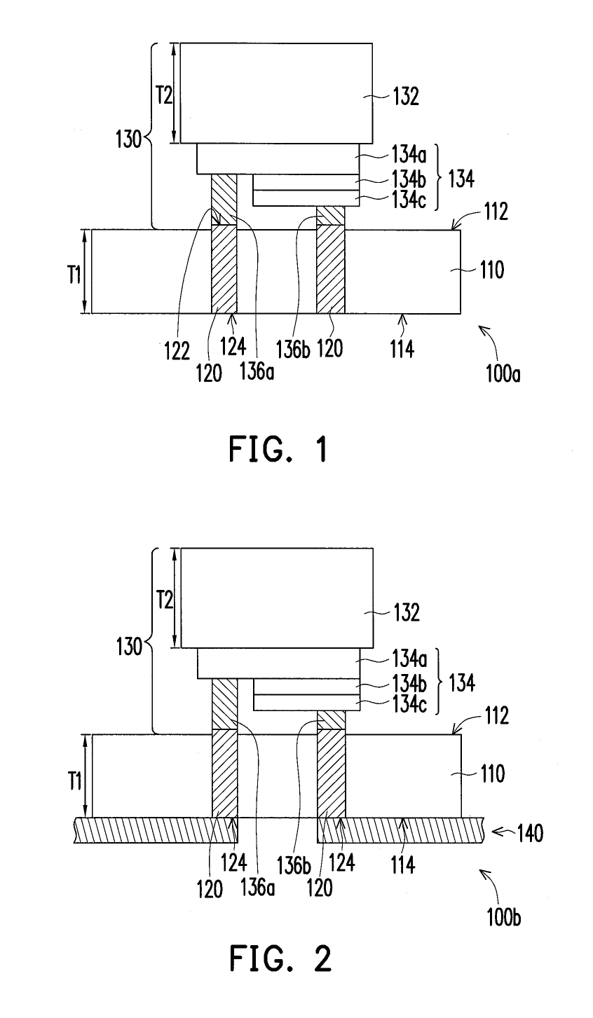

FIG. 1 is a schematic cross-sectional view of an electronic device according to an embodiment of the present invention. Referring to FIG. 1, in the embodiment, the electronic device 100a includes an insulating substrate 110, a plurality of conductive vias 120 and a chip 130. In more detailed, the insulating substrate 110 has an upper surface 112 and a lower surface 114 opposite to the upper surface 112. The conductive vias 120 pass through the insulating substrate 110. The chip 130 is disposed on the upper surface 112 of the insulating substrate 110. The chip 130 includes a chip substrate 132, a semiconductor layer 134 and a plurality of contacts 136a, 136b. Herein, the semiconductor layer 134 is located between the chip substrate 132 and the contacts 136a, 136b, and the contacts 136a, 136b are electrically connected to the conductive vias 120. Specifically, materials of the insulating substrate 110 and the chip substrate 132 are substantially the same.

More specifically, the chip 130 of the present invention can be a chip of flip-chip light emitting device (LED), wherein the semiconductor layer 134 includes an N-type doped layer 134a, a light emitting layer 134b and a P-type doped layer 134c. The light emitting layer 134b is located between the N-type doped layer 134a and the P-type doped layer 134c. The contacts 136a, 136b are electrically connected to the N-type doped layer 134a and the P-type doped layer 134c, respectively. In addition, in this embodiment, the conductive vias 120 pass through the insulating substrate 110, and an end 122 of each of the conductive vias 120 protrudes from the upper surface 112 of the insulating substrate 110 and electrically connected to the contacts 136a, 136b respectively. The other end 124 of each of the conductive vias 120 and the lower surface 114 of the insulating substrate 110 are substantially coplanar. Certainly, in other embodiments not shown in figures, the end 122 of each of the conductive vias 120 and the upper surface 112 of the insulating substrate 110 can substantially be coplanar, whereas the other end 124 of each of the conductive vias 120 protrudes from the lower surface 114 of the insulating substrate 110. As long as the electrically connecting effect between the conductive vias 120 and the contacts 136a, 136b can be achieved, the structure design still falls within the technical schemes adopted by the present invention without departing from the scope of the present invention.

In order to place the heat generated by the chip 130 during light emitting into the insulating substrate 110 and to prevent the reduction of light emitting efficiency due to the heat accumulated in chip 130, preferably, the specific heat of both the insulating substrate 110 and the chip substrate 132 are higher than 650 J/Kg-K, and the coefficient of thermal conductivity of both the insulating substrate 110 and the chip substrate 132 are greater than 10 W/m-K. In addition, in order to increase the light extraction efficiency, it should prevent the insulating substrate 110 to absorb light emitted by the light emitting layer 134b, and thus the insulating substrate 110 and the chip substrate 132 can be transparent insulating substrates, for example. For instance, the insulating substrate 110 and the chip substrate 132 can be glass substrates, gallium arsenide (GaAs) substrates, gallium nitride (GaN) substrates, aluminum nitride (AlN) substrates, sapphire substrates, silicon carbide (SiC) substrates or the like. In order to concurrently process properties of transparency and high capacitor, preferably, the insulating substrate 110 and the chip substrate 132 can be sapphire substrates. Specifically, the thickness of the insulating substrate 110 of the embodiment is smaller than or equal to the thickness of the chip substrate 132, and preferably, the thickness T1 of the insulating substrate 110 is 0.6 to one times the thickness T2 of the chip substrate 132. Moreover, the specific surface area of the insulating substrate 110 is greater than the specific surface area of the chip substrate 132, and preferably, the specific surface area of the insulating substrate 110 is greater than 1.1 times of the specific surface area of the chip substrate 132.

Since the materials of the insulating substrate 110 and the chip substrate 132 of the chip 130 are the same, when the heat generated by the chip 130 is transferred to the insulating substrate 110, the insulating substrate 110 and the chip substrate 132 having the same heat dissipating capacity, i.e., the coefficient of thermal conductivity being the same, the heat generated by the chip 130 can be more effectively transferred to the external environment. Thus, the electronic device 100a of the present embodiment has better heat dissipating efficiency. In addition, since the specific heat of both of the insulating substrate 110 and the chip substrate 132 are higher than 650 J/Kg-K, the insulating substrate 110 can receive and accumulate much more heat. Furthermore, since the coefficient of thermal conductivity of the insulating substrate 110 and the chip substrate 132 are greater than 10 W/m-K and the insulating substrate 110 has a comparatively larger specific surface area and a smaller thickness relative to the chip substrate 132, the heat generated by the chip 130 can be more effectively transferred to the external environment, so as to prevent the chip 130 from problems of brightness reducing, lifespan shortening and damaged permanently due to being overheated.

It has to be noted that, the embodiment described below uses the same reference numerals and part of contents of the previous embodiment, wherein the same reference numerals are referred to the same or similar components, and the same description is not repeated. The relevant illustration can be referred to the previous embodiment and is not omitted in the embodiment described below.

FIG. 2 is a schematic cross-sectional view of an electronic device according to another embodiment of the present invention. Referring to FIG. 2, in the present embodiment, the electronic device 100b is similar to the electronic device 100a. A difference between the two lies in that, the electronic device 100b further includes an external circuit 140, wherein the chip 130 is electrically connected to the external circuit 140 through the other end 124 of each of the conductive vias 120. The external circuit 140 is a lead frame, for example. Since the chip 130 of the electronic device 100b of the embodiment can be electrically connected to the external circuit 140 through the conductive vias 120, the application range of the electronic device 100b can be increased.

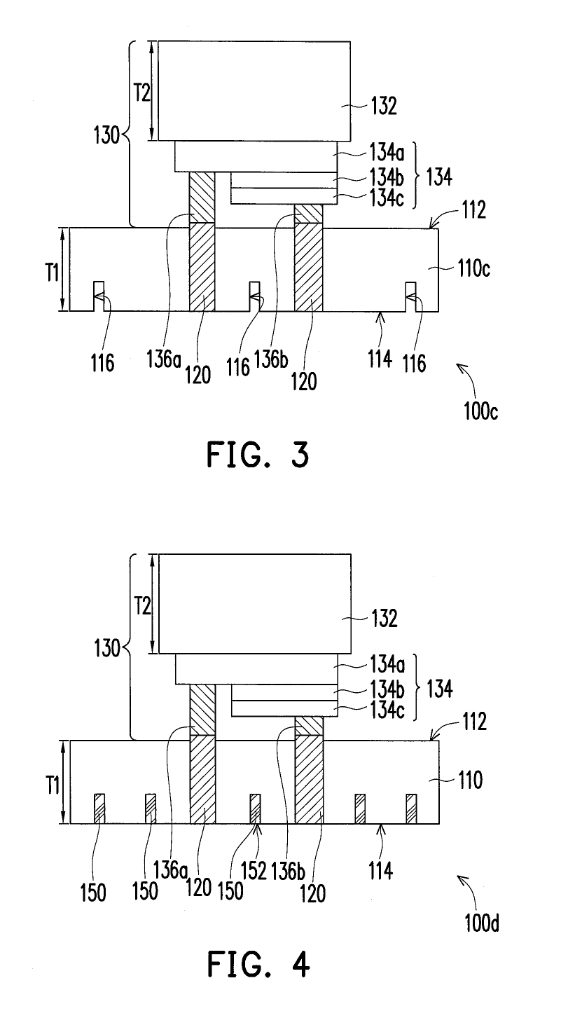

FIG. 3 is a schematic cross-sectional view of an electronic device according to another embodiment of the present invention. Referring to FIG. 3, in the present embodiment, the electronic device 100c is similar to the electronic device 100a. A difference between the two lies in that, the insulating substrate 110c of the electronic device 100c further has at least one blind via 116 (only three blind vias 116 are shown in FIG. 3), wherein the blind vias 116 are disposed on the lower surface 114 of the insulating substrate 110c. Since the insulating substrate 110c has blind vias 116 disposed thereon, heat convection can be increased so that the heat dissipating efficiency of the electronic device 100c is improved.

FIG. 4 is a schematic cross-sectional view of an electronic device according to another embodiment of the present invention. Referring to FIG. 4, in the present embodiment, the electronic device 100d is similar to the electronic device 100a. A difference between the two lies in that, the electronic device 100d further includes at least one heat dissipating element 150 (only five heat dissipating elements 150 are shown in FIG. 4), wherein the heat dissipating elements 150 are embedded in the lower surface 114 of the insulating substrate 110, and a surface 152 of each of the heat dissipating elements 150 is substantially coplanar to the lower surface 114 of the insulating substrate 110. In addition, the heat dissipating elements 150 are formed by metal (e.g., gold, aluminum or copper), metal alloy or heat dissipating posts or heat dissipating blocks formed by other suitable materials for heat conductivity, for example. Accordingly, when the heat generated by the chip 130 is transferred to the insulating substrate 110, the heat can be transferred to the external environment simultaneously through the insulating substrate 110 and the heat dissipating elements 150, and heat dissipating efficiency of the electronic device 100d can be effectively improved.

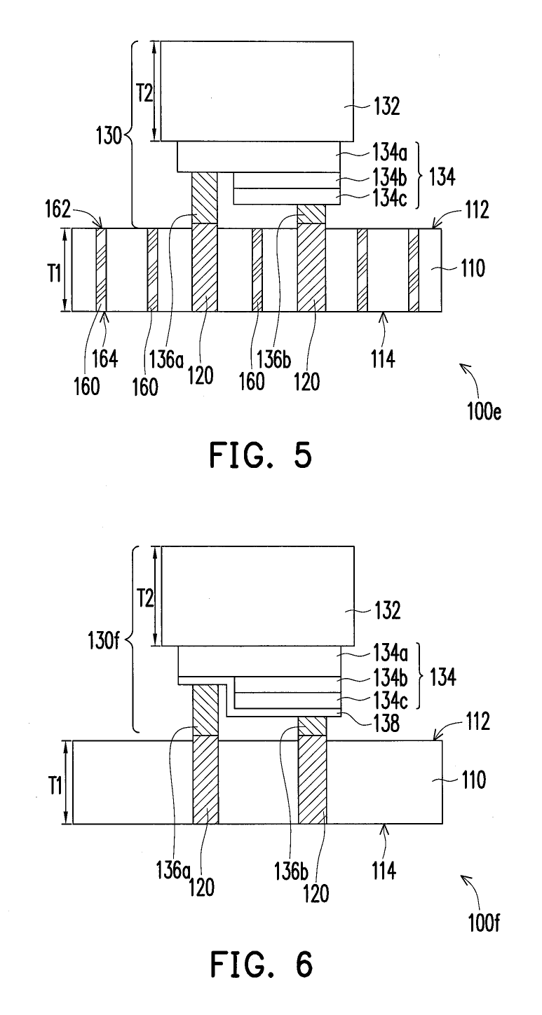

FIG. 5 is a schematic cross-sectional view of an electronic device according to another embodiment of the present invention. Referring to FIG. 5, in the present embodiment, the electronic device 100e is similar to the electronic device 100a. A difference between the two lies in that, the electronic device 100e further includes a plurality of heat dissipating channels 160 (only five heat dissipating channels 160 are shown in FIG. 5), wherein the heat dissipating channels 160 pass through the insulating substrate 110, and a top surface 162 of each of the heat dissipating channels 160 is substantially coplanar to the upper surface 112 of the insulating substrate 110, and a bottom surface 164 of each of the heat dissipating channels 160 is substantially coplanar to the lower surface 114 of the insulating substrate 110. Accordingly, when the heat generated by the chip 130 is transferred to the insulating substrate 110, the heat can be transferred to the external environment simultaneously through the insulating substrate 110 and the heat dissipating channels 160, and heat dissipating efficiency of the electronic device 100e can be effectively improved. Especially, the heat dissipating channel 160 can be an air channel, i.e., a hollow channel without filler, or can be formed by filling with metal (e.g., gold, aluminum or copper), metal alloy or channels formed by other suitable materials filled in for heat conductivity. Herein the heat dissipating channels 160 are formed by metal filling and shown in FIG. 5 as an example, but the present invention is not limited thereto.

FIG. 6 is a schematic cross-sectional view of an electronic device according to another embodiment of the present invention. Referring to FIG. 6, in the present embodiment, the electronic device 100f is similar to the electronic device 100a. A difference between the two lies in that, the chip 130f of the electronic device 100f further includes a reflective layer 138, wherein the reflective layer 138 is disposed between the semiconductor layer 134 of the chip 130f and the contacts 136a, 136b, and the reflective layer 138 is used to improve the illumination efficiency of the chip 130f so that the electronic device 100f has a better illumination efficiency.

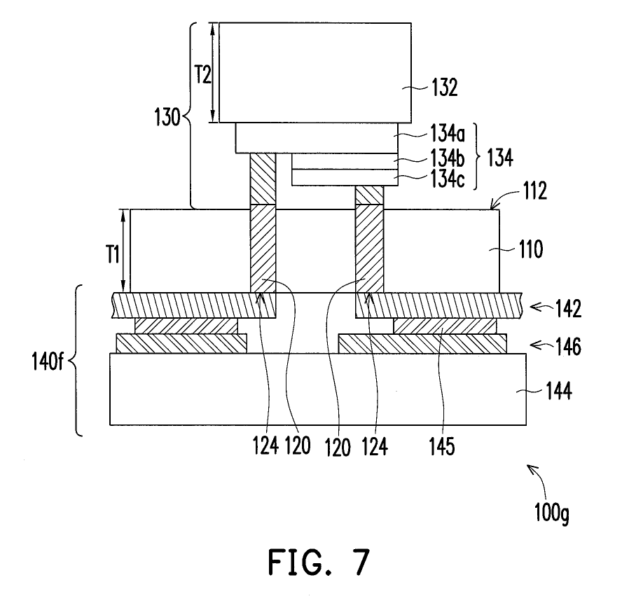

FIG. 7 is a schematic cross-sectional view of an electronic device according to another embodiment of the present invention. Referring to FIG. 7, in the present embodiment, the electronic device 100g is similar to the electronic device 100a. A difference between the two lies in that, the electronic device 100g further includes an external circuit 140f, wherein the chip 130 is electrically connected to the external circuit 140f through the conductive vias 120. Herein, the external circuit 140f is formed by, for example, assembling a lead frame 142 and a printed circuit board 144, wherein the lead frame 142 is electrically connected to the other end 124 of each of the conductive vias 120, and the conductive vias 142 is electrically connected to a circuit layer 146 on the printed circuit board 144 through a plurality of conductive bumps 145 (e.g., solder bumps or gold bumps). Thus, the application range of the electronic device 100f can be effectively increased.

It has to be noted that, the structure of the external circuits 140, 140f is not limited in the present invention. Though the external circuit 140 is abstractly referred to the lead frame and the external circuit 140f is referred to an assembly of the lead frame 142 and the printed circuit board 144. In other embodiments not shown in the figures, the external circuit 140 can also be a lead frame, a circuit substrate, a printed circuit board or a combination thereof, which still falls within the technical schemes adopted by the present invention without departing from the scope of the present invention. In addition, the design of above mentioned blind vias 116, reflective layer 136, external circuit 140, 140f, heat dissipating elements 150 and heat dissipating channels 160 can be applied to other embodiments not shown in the figures. Persons with ordinary skill in the art may refer to the above embodiments and use the above mentioned components according to the actual requirements, so as to achieve the satisfactory effect.

In light of the foregoing, since the materials of the insulating substrate and the chip substrate are the same in the present invention, when the heat generated by the chip is transferred to the insulating substrate, the insulating substrate and the chip substrate having the same heat dissipating capacity, i.e., their coefficient of thermal conductivity being, the heat generated by the chip can be more effectively transferred to the external environment. Thus, the electronic device of the present invention has better heat dissipating efficiency. In addition, since the specific heat of both of the insulating substrate and the chip substrate are higher than 650 J/Kg-K, the insulating substrate can receive and accumulate much more heat. Moreover, since the coefficient of thermal conductivity of the insulating substrate and the chip substrate are greater than 10 W/m-K and the insulating substrate has a comparatively larger specific surface area and a smaller thickness relative to the chip substrate, the heat generated by the chip can be more effectively transferred to the external environment, so as to prevent the chip from problems of brightness reducing, lifespan shortening and damaged permanently due to being overheated.

Though the disclosure has been disclosed above by the embodiments, they are not intended to limit the disclosure. Persons skilled in the art may make some modifications and variations without departing from the spirit and scope of the disclosure. Therefore, the protecting range of the disclosure falls in the appended claims.

What is claimed is:

1. An electronic device, comprising:
an insulating substrate having an upper surface and a lower surface opposite to the upper surface;
a plurality of conductive vias passing through the insulating substrate; and
a chip disposed on the upper surface of the insulating substrate and comprising a chip substrate, a semiconductor layer and a plurality of contacts, wherein the semiconductor layer is located between the chip substrate and the contacts, and the contacts are electrically connected to the conductive vias, and a material of the insulating substrate and a material of the chip substrate are the same.

2. The electronic device as claimed in claim 1, wherein a specific heat of the insulating substrate and a specific heat of the chip substrate are higher than 650 J/Kg-K.

3. The electronic device as claimed in claim 1, wherein a coefficient of thermal conductivity of the insulating substrate and a coefficient of thermal conductivity of the chip substrate are greater than 10 W/m-K.

4. The electronic device as claimed in claim 1, wherein both of the insulating substrate and the chip substrate are transparent insulating substrates.

5. The electronic device as claimed in claim 1, wherein the chip further comprises a reflective layer disposed between the semiconductor layer and the contacts.

6. The electronic device as claimed in claim 1, further comprising an external circuit, wherein the chip is electrically connected to the external circuit through the conductive vias.

7. The electronic device as claimed in claim 6, wherein the external circuit comprises a lead frame, a circuit substrate or a printed circuit board.

8. The electronic device as claimed in claim 1, further comprising at least one heat dissipating element embedded in the lower surface of the insulating substrate.

9. The electronic device as claimed in claim 1, wherein the insulating substrate further has at least one blind via disposed on the lower surface of the insulating substrate.

10. The electronic device as claimed in claim 1, further comprising a plurality of heat dissipating channels passing through the insulating substrate, wherein a top surface of each of the heat dissipating channels and the upper surface of the insulating substrate are coplanar, and a bottom surface of each of the heat dissipating channels and the lower surface of the insulating substrate are coplanar.

11. The electronic device as claimed in claim 1, wherein a thickness of the insulating substrate is smaller than or equal to a thickness of the chip substrate.

12. The electronic device as claimed in claim 11, wherein the thickness of the insulating substrate is 0.6 to one times the thickness of the chip substrate.

13. The electronic device as claimed in claim 1, wherein a specific surface area of the insulating substrate is greater than a specific surface area of the chip substrate.

14. The electronic device as claimed in claim 13, wherein the specific surface area of the insulating substrate is greater than 1.1 times the specific surface area of the chip substrate.
